(19) United States
(12) Patent Application Publication
(10) Pub. No.: US 2010/0078706 A1
(43) Pub. Date: Apr. 1, 2010

(54) Nonvolatile semiconductor memory device and method of manufacturing nonvolatile semiconductor memory device

(75) Inventor: Tomoko Matsuda, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/585,826

(22) Filed: Sep. 25, 2009

(30) Foreign Application Priority Data
Sep. 29, 2008 (JP) 2008-251758

(51) Int. Cl. H01L 29/792; H01L 21/28

(52) U.S. Cl. 257/326; 438/591; 257/E29.309; 257/E21.21

(57) ABSTRACT

A nonvolatile semiconductor memory device (and method of forming same) includes a word gate provided above a channel region of a semiconductor substrate via an insulating layer, a control gate provided at a side of the word gate, and a charge storage layer provided by an ONO film between the channel region and the control gate, and between the word gate and the control gate. The control gate includes a silicide layer including silicide containing nickel, and a non-silicide layer provided between the silicide layer and the charge storage layer.

### INCORPORATION BY REFERENCE

This application is based upon and claims the benefit of priority from Japanese Patent Application No. 2008-251758 which was filed on Sep. 29, 2008, the disclosure of which is incorporated herein in its entirety by reference.

### BACKGROUND OF THE INVENTION

1. Field of the Invention

The present invention relates to a nonvolatile semiconductor memory device, and to a method of manufacturing a nonvolatile semiconductor memory device.

2. Description of Related Art

A nonvolatile semiconductor memory device with a Metal-Oxide-Nitride-Oxide-Silicon (MONOS) structure is known. The nonvolatile semiconductor memory device includes a word gate provided above a channel region of a semiconductor substrate via an insulating layer, control gates provided at both sides of the word gate, and a charge storage layer provided both between the channel region and the control gate, and between the word gate and the control gate. An Oxide Nitride Oxide (ONO) film is used for the charge storage layer.

In nonvolatile semiconductor memory devices, a control gate has been thinned with the miniaturization of semiconductor elements. Together with thinning the gate, the control gate can have an increased resistance. Thus, in order to address the increased resistance, a method for siliciding an upper part of the control gate has been proposed. However, the use of cobalt silicide or titanium silicide material makes it difficult to sufficiently decrease the resistance by the thinning effect of the silicide. Thus, the miniaturization using these materials has become difficult. Since a part of the control gate not silicided still has a high resistance, it is preferable to silicide the control gate in a wide area (thickness) as much as possible. On the other hand, a diffusion layer region and a peripheral transistor are also silicided at the same time. When such a silicided part becomes thick, problems including an increase in leakage at the diffusion layer may be caused.

A nonvolatile semiconductor memory device is disclosed in, for example, JP-A-2005-228786. FIG. 1 is a sectional view showing the structure of the nonvolatile semiconductor memory device disclosed in JP-A-2005-228786. The nonvolatile semiconductor memory device includes diffusion layer electrodes 132, a gate insulating film 112, agate (word gate) 122, a silicide layer (control gate) 124, a memory gate insulating film (charge storage layer) 114, insulating films 116, and silicide layers 134 and 135. In the nonvolatile semiconductor memory device, the memory gate insulating film 114 is formed of an ONO film. The silicide layer 124 (control gate) and the silicide layers 134 and 135 are produced using nickel silicide. The silicide layer 124 (control gate) is made of nickel silicide so that no increase in resistance occurs due to the thinning, due to the fact that the thinner control gate can be more easily silicided fully by acceleration of the reaction, and the like. This can achieve both decrease in thickness and resistance of the control gate, and shallow junction of a diffusion region and the like.

### SUMMARY

However, the present inventor has recognized the following point. Namely, the technique disclosed in JP-A-2005-228786 has the following problems. When the gate (word gate) 122 and the diffusion layer electrodes 132 are silicided (to form the silicide layers 134 and 135), the memory gate insulating film (charge storage layer) 114 which is the ONO film already has a section of an upper end exposed. When a silicide step is performed while the section of the ONO film is being exposed in this way, a silicide film is formed in the ONO film because nickel components attached onto the nitride film of the ONO film are easily subjected to a silicide reaction with silicon in the nitride film. Then, even when the excessive nickel components are removed by etching, the silicide film is not removed, and remains on the ONO film. As a result, the silicide layer (control gate) 124 and the gate (word gate) 122 may be short-circuited due to the remaining silicide film. A technique for preventing short-circuiting between the ONO film and the control gate is desired.

Additionally, in this structure, the silicide layer (control gate) 124 which is the silicide film is in direct contact with the memory gate insulating film (charge storage layer) 114 serving as a charge storage region. That is, nickel silicide which has an extremely low resistance as compared to polysilicon, comes into direct contact with the ONO film. Thus, it is thought that charges stored in a nitride film of the ONO film are very easily affected by an electric state of the nickel silicide (for example, variations in voltage), or a state of an oxide film (for example, uniformity in film thickness) located on the nickel silicide side of the ONO film. Thus, the electric state and the film thickness state can make the state of charges stored in the nitride film extremely unstable, and make the distribution of charges nonuniform. In particular, nickel components of the nickel silicide may be partly diffused into the oxide film on the nickel silicide side to degrade the quality of the ONO film. In that case, the charges stored in the nitride film can be prone to penetrate the nickel components. In this way, such occurrence of unstable charges and nonuniform electrolytic distribution at the ONO film, and degradation in quality of the ONO film leads to a crash of data, which may significantly reduce reliability and stability of a memory cell. Thus, there is a need for a technique that prevents the instability of charges and nonuniformity of electrolytic distribution at the ONO film and the degradation in quality of the ONO film, thereby to enhance the reliability and stability of the memory cell.

The present invention seeks to solve one or more of the above problems, or to improve upon those problems at least in part.

In one exemplary embodiment, a nonvolatile semiconductor memory device includes a word gate provided above a channel region of a semiconductor substrate via an insulating layer, a control gate provided at a side of the word gate, and a charge storage layer provided by an ONO film between the channel region and the control gate, and between the word gate and the control gate. The control gate includes a silicide layer including silicide containing nickel, and a non-silicide layer provided between the silicide layer and the charge storage layer.

In this exemplary embodiment, the silicide layer is provided by silicide containing nickel. Therefore, the resistance of the control gate can be made lower. On the other hand, the non-silicide layers are provided between the silicide layer and the charge storage layer, thereby separating both layers. Thus, even when a nitride film exposed to the section of the ONO film is partly silicided, the silicide layer is spaced more apart from the word gate, which can prevent short-circuiting. The silicide layer is configured not to be in direct contact with the ONO film by a presence of the non-silicide layers. Thus, the influences of the electric state of the silicide layer, and of the state of an oxide film on the silicide layer side of the ONO film can be reduced to a much smaller level. The nickel components of the silicide layer are prevented from being diffused into the ONO film, so that the charges stored in the nitride film can be prevented from being drawn into the nickel components. Such an arrangement can stabilize more the state of charges stored in the nitride film, make the charge distribution more uniform, and prevent the degradation in quality of the ONO film. As a result, the reliability and stability of the memory cell can be enhanced.

In another exemplary embodiment, a method of manufacturing a nonvolatile semiconductor memory device includes forming an ONO film so as to cover a word gate formed above a semiconductor substrate via an insulating layer, forming a polysilicon film so as to cover the ONO film, forming a control gate at a side of the word gate via the ONO film by etching the polysilicon film, etching the ONO film over the word gate and outside the control gate, siliciding an upper part of the word gate, a part of the control gate, and a part outside the control gate by forming a metal film including nickel over an entire surface and applying heat treatment thereto, and removing the metal film. The forming of the polysilicon film includes forming the polysilicon film while temporarily mixing an additive gas including at least one of oxygen and carbon into a film-forming gas during forming the polysilicon film.

In this exemplary embodiment, in the forming of the polysilicon film, the polysilicon films are formed while temporarily mixing the additive gas containing at least one of oxygen and carbon into the film forming gas during forming the film. Thus, the control gate has a three-layered structure of the polysilicon film obtained before mixing of the additive gas, the polysilicon film obtained during mixing of the additive gas, and the polysilicon film obtained after mixing of the additive gas. Among them, the polysilicon film is silicided in the silicide step to become the silicide layer. The polysilicon film inhibits the diffusion of nickel by the effect of oxygen or carbon in the additive gas, thus becoming the silicide reaction inhibition layer for inhibiting the silicide reaction. Since the silicide reaction inhibition layer inhibits the diffusion of nickel, the polysilicon film becomes the polysilicon layer not silicided. The silicide reaction inhibition layer and the polysilicon film are together referred to as the non-silicide layer. A nonvolatile semiconductor memory device manufactured in such steps has the same operation and effect as those of the above-mentioned nonvolatile semiconductor memory device.

The invention can prevent short-circuiting between the word gate and the control gate. The instability of charges and nonuniformity of electrolytic distribution at the ONO film, the degradation in quality of the ONO film, and the like can be prevented, which can enhance the reliability and stability of the memory cell.

### BRIEF DESCRIPTION OF THE DRAWINGS

The above and other purposes, advantages and features of the present invention will become more apparent from the following description of a certain exemplary embodiment taken in conjunction with the accompanying drawings in which:

FIG. 1 is a cross-sectional view showing the structure of a nonvolatile semiconductor memory device disclosed in JP-A-2005-228786;

FIG. 2 is a cross-sectional view showing the structure of a nonvolatile semiconductor memory device according to a first exemplary embodiment of the invention;

FIG. 3 is a top view showing the structure of the nonvolatile semiconductor memory device according to the first exemplary embodiment of the invention;

FIG. 4A is a cross-sectional view showing a first step in a method for manufacturing the nonvolatile semiconductor memory device according to the first exemplary embodiment of the invention;

FIG. 4B is a cross-sectional view showing a second step in a method for manufacturing the nonvolatile semiconductor memory device according to the first exemplary embodiment of the invention;

FIG. 4C is a cross-sectional view showing a third step in a method for manufacturing the nonvolatile semiconductor memory device according to the first exemplary embodiment of the invention;

FIG. 4D is a cross-sectional view showing a fourth step in a method for manufacturing the nonvolatile semiconductor memory device according to the first exemplary embodiment of the invention;

FIG. 5A is a cross-sectional view showing a fifth step in a method for manufacturing the nonvolatile semiconductor memory device according to the first exemplary embodiment of the invention;

FIG. 5B is a cross-sectional view showing a sixth step in a method for manufacturing the nonvolatile semiconductor memory device according to the first exemplary embodiment of the invention;

FIG. 5C is a cross-sectional view showing a seventh step in a method for manufacturing the nonvolatile semiconductor memory device according to the first exemplary embodiment of the invention;

FIG. 5D is a cross-sectional view showing an eighth step in a method for manufacturing the nonvolatile semiconductor memory device according to the first exemplary embodiment of the invention;

FIG. 6A is a cross-sectional view showing a ninth step in a method for manufacturing the nonvolatile semiconductor memory device according to the first exemplary embodiment of the invention;

FIG. 6B is a cross-sectional view showing a tenth step in a method for manufacturing the nonvolatile semiconductor memory device according to the first exemplary embodiment of the invention;

FIG. 6C is a cross-sectional view showing an eleventh step in a method for manufacturing the nonvolatile semiconductor memory device according to the first exemplary embodiment of the invention;

FIG. 6D is a cross-sectional view showing a twelfth step in a method for manufacturing the nonvolatile semiconductor memory device according to the first exemplary embodiment of the invention;

FIG. 7A is a cross-sectional view showing a thirteenth step in a method for manufacturing the nonvolatile semiconductor memory device according to the first exemplary embodiment of the invention;

FIG. 7B is a cross-sectional view showing a fourteenth step in a method for manufacturing the nonvolatile semiconductor memory device according to the first exemplary embodiment of the invention; and

FIG. 7C is a cross-sectional view showing a fifteenth step in a method for manufacturing the nonvolatile semiconductor memory device according to the first exemplary embodiment of the invention.

### DETAILED DESCRIPTION OF THE EXEMPLARY EMBODIMENT

The invention will now be described herein with reference to an illustrative exemplary embodiment. Those skilled in the art will recognize that many alternative embodiments can be accomplished using the knowledge of the present invention, and that the invention is not limited to the exemplary embodiment illustrated for explanatory purposes.

### First Exemplary Embodiment

FIG. 2 is a cross-sectional view showing the structure of a nonvolatile semiconductor memory device according to a first exemplary embodiment of the invention. In the first exemplary embodiment, a flash memory cell having a TWIN-MONOS structure will be described as one example of a memory cell of the nonvolatile semiconductor memory device. The TWIN-MONOS structure is a structure having control gates formed at both sides of a word gate.

A memory cell 1 includes source/drain diffusion layers 32, a word gate insulating film 12, a word gate 22, control gates 24, ONO films (oxide nitride oxide films: oxide-nitride-oxide films) 14, sidewall insulating films 16, silicide layers 34 and 35, and LDD (lightly doped drain) diffusion layers 31.

The source/drain diffusion layers 32 are formed on both sides of the channel region over the surface of a semiconductor substrate 10. A dopant of the source/drain diffusion layer 32 may be, for example, arsenic (As), or phosphorus (P). The LDD diffusion layer 31 is substantially formed directly under the sidewall insulating film 16 so as to overhang from the source/drain diffusion layer 32 into the channel region. The dopant may be, for example, arsenic (As), or phosphorus (P). The silicide layers 34 and 35 are formed above the word gate 22 and the source/drain diffusion layer 32, respectively. The silicide layers 34 and 35 are made of silicide containing nickel, for example, nickel silicide, or nickel-platinum silicide.

The word gate insulating film 12 is formed in the channel region sandwiched between the source/drain diffusion layers 32. The word gate insulating film 12 is made of, for example, silicon oxide. The word gate 22 is formed over the channel region via the word gate insulating film 12. The word gate 22 is formed of a conductor into which impurities are doped so as to form an electrode (word gate), which is, for example, activated polysilicon doped with phosphorus (P), or arsenic (As). For example, a silicide layer 34 is formed on the word gate 22. The word gate has a width in the y-direction of 60 nm to 90 nm, for example. It has a height in the z-direction of 60 nm to 250 nm.

The control gates 24 are formed at both sides of the word gate 22 via the ONO films 14, and above the channel region via the ONO films 14. The control gate 24 is formed to have a narrow width corresponding to the miniaturization, but enough height to compensate therefor. That is, the width in the y-direction of the control gate 24 shown in FIG. 2 is smaller than the height in the z-direction of the gate. For example, the width of the control gate is 10 nm to 60 nm, and the height thereof is 50 nm to 200 nm. The control gate 24 includes a silicide layer 24a and non-silicide layers (24b, 24c).

The silicide layer 24a is a main area of the control gate 24, and made of silicide which sufficiently decreases the resistance of the control gate 24 for high-speed operation. The silicide is, for example, nickel silicide, or nickel-platinum silicide. In particular, in the case of siliciding by use of nickel or metal containing nickel, when the polysilicon is thinned, a silicide reaction is accelerated, so that the polysilicon can be entirely silicided uniformly from its upper part to its bottom part in the thickness direction (z-direction), and thus can have its resistance decreased. The silicide layer 24a is entirely silicided, thus decreasing a resistance of the control gate 24.

The non-silicide layers (24b, 24c) are provided between the silicide layer 24a and the ONO film 14. The non-silicide layers (24b, 24c) can separate additionally the silicide layer 24a from the word gate 22. Thus, even when a nitride film exposed to the section of the ONO film 14 is partly silicided in the silicide step, the occurrence of short-circuiting between the control gate 24 and the word gate 22 can be prevented. The non-silicide layers include a silicide reaction inhibition layer 24b, and a polysilicon layer 24c.

The silicide reaction inhibition layer 24b is provided between the silicide layer 24a and the ONO film 14. The silicide reaction inhibition layer 24b is formed of silicon containing at least one of oxygen and carbon. When the silicide layer 24a is formed, the silicide reaction inhibition layer 24b inhibits the diffusion of metal atoms for siliciding, thereby to prevent siliciding of the inhibition layer itself. This can inhibit the diffusion of the metal atoms into the polysilicon layer 24c to prevent the siliciding, and can maintain the state of the polysilicon. As a result, metal components, such as nickel, of the silicide layer 24a can be prevented from approaching the ONO film 14 and being diffused thereinto. It is noted that the silicide reaction inhibition layer 24b is formed extremely thinly to such a degree as not to inhibit an electric function of the control gate 24 mainly based on the silicide layer 24a and the polysilicon layer 24c.

The oxygen and carbon contents of the silicide reaction inhibition layer 24b are determined by simulation and experiments according to a capacity for inhibiting the silicide reaction required of the silicide reaction inhibition layer 24b (hereinafter referred to as a “silicide inhibiting capacity”). For example, when silicide layers 34 and 35 are intended to be formed thickly taking into consideration a relationship between the silicide layer 24c and the silicide layers 34 and 35 formed at the same time, it is necessary to further increase the temperature of heat treatment of the silicide, or to further prolong the time of heat treatment. In this case, in order not to allow the polysilicon layer 24c to be silicided, it is required to further enhance a silicide inhibition capacity of the silicide reaction inhibition layer 24b. The oxygen and carbon contents are further increased so as to enhance the silicide inhibition capacity. The thickness of the inhibition layer 24b is increased when possible from the viewpoint of electrical properties and space, which can further enhance the silicide inhibition capacity.

The polysilicon layer 24c is provided between the silicide reaction inhibition layer 24b and the ONO film 14. The polysilicon layer 24c is formed of a conductor into which impurities are introduced so as to form an electrode (control gate), and is, for example, an activated polysilicon doped with arsenic (As) or phosphorus (P). The arsenic (As) is less prone to diffusion into the ONO film 14 as compared to the phosphorus (P), and thus the dopant is preferably arsenic (As). The polysilicon layer 24c achieves its inherent function as the control gate 24 together with the silicide layer 24a.

In the memory cell 1, the silicide layer 24a does not come into direct contact with the ONO film 14 due to the polysilicon layer 24c intervening therebetween. That is, an interface between the ONO film 14 and the control gate 24 corresponds to an interface between the polysilicon film (polysilicon layer 24c) and the oxide film (ONO film 14), like the nonvolatile semiconductor memory device with the typical MONOS structure. Thus, charges stored in the nitride film of the ONO film 14 are not affected much by the electric state of the silicide layer 24a (for example, variations in voltage), or the state of an oxide film located on the silicide layer 24a side of the ONO film 14 (for example, uniformity in film thickness). And, the pulling out of the charges is not caused due to the diffusion of nickel components. That is, since the entire silicide layer 24a is silicided and thus has the extremely low resistance, the relationship between the ONO film 14 and the control gate 24 can ensure the very stable charge state and operation.

The word gate 22 and the control gate 24 of the first exemplary embodiment are formed of polysilicon as a base material. It is noted that the invention is not limited to the first exemplary embodiment, and that material containing at least one of polysilicon and poly-germanium can be used for the control gate 24. Also, in this case, the same effects as those of the above-mentioned word gate 22 and control gate 24 can be obtained.

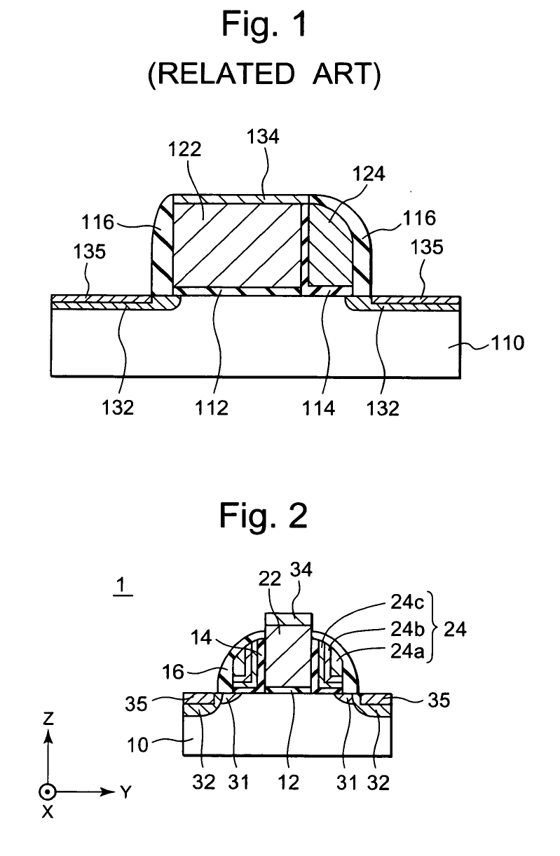

In the TWIN-MONOS structure of the first exemplary embodiment, two control gates 24 are provided per memory cell 1 at both sides of the word gate 22. It is noted that the invention is not limited to the first exemplary embodiment, and that like the example shown in FIG. 1, only one control gate may be provided on one side. Further, the ONO film 14 is not limited to the substantially L-like shape, and may have a planar shape. In that case, one control gate is mounted on the ONO film in a planar manner.

The ONO film 14, which is a charge storage layer, is formed between the word gate 22 and the control gate 24, and between the control gate 24 and the channel region (semiconductor substrate 10). The ONO film 14 has a three-layer structure of oxide film/nitride film/oxide film, specifically, which is made of a silicon oxide film, a silicon nitride film, and a silicon oxide film, in that order. In the TWIN-MONOS structure shown, the ONO film 14 has the substantially L-like shape. In the planar-type MONOS structure, the ONO film has the planar shape.

The sidewall insulating films 16 are formed at both sides of the word gate 22 to cover the control gates 24. The sidewall insulating film is, for example, a single layer film made of silicon oxide, or a laminated film of silicon oxide, silicon nitride, and silicon oxide laminated in that order. The control gates 24 of the adjacent memory cells 1 are insulated from each other by being enclosed with the respective sidewall insulating films 16 or interlayer insulating layers (not shown).

As mentioned above, in the memory cell 1 of the first exemplary embodiment, the control gate 24 includes the silicide layer 24a and the non-silicide layers (24b, 24c), which can prevent short-circuiting between the control gate 24 and the word gate 22, while achieving a decrease in resistance of the control gate 24 required for high-speed operation. Thus, the state of charges stored in the nitride film of the ONO film 14 can be made more stable, and the distribution of charges can be made more uniform, which can contribute to a stable operation. Additionally, metal components of the silicide layer 24a can be prevented from being diffused into the ONO film 14. Such an arrangement can prevent degradation of quality of ONO film 14, and thus can enhance the reliability and stability of the memory cell.

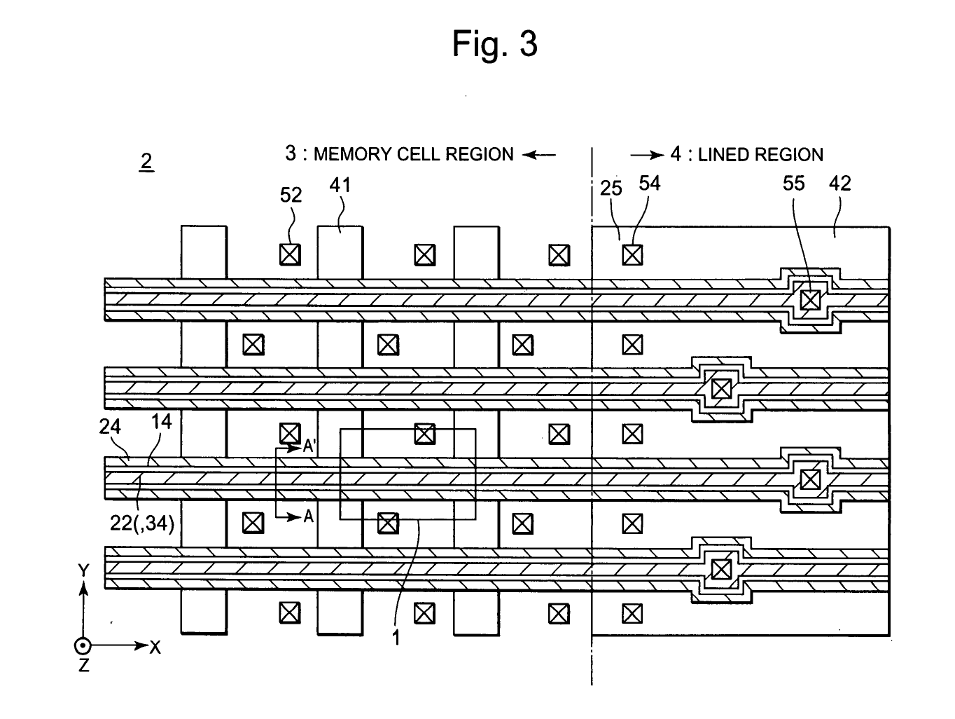

FIG. 3 is a top view showing the structure of the nonvolatile semiconductor memory device according to the first exemplary embodiment of the invention. In the figure, the illustration of the source/drain diffusion layer 32, the sidewall insulating film 16, and the silicide layers 34 and 35 is omitted.

A memory array 2 of the nonvolatile semiconductor memory device includes a memory cell region 3 and a lined region 4.

The word gate 22 extends in the x-direction in the memory cell region 3 and the lined region 4. The control gates 24 extend in the x-direction along both sides of the word gate 22 via the ONO films 14 in the memory cell region 3 and the lined region 4. The word gate 22 and the control gate 24 are shared among plural memory cells 1 in the X-direction, and serve as wiring.

In the memory cell region 3, plural element isolation regions 41 for electrically separating a surface area are formed to extend in the Y-direction. The memory-cell region 3 includes plural memory cells 1 arranged in an array. The memory cell 1 is sandwiched between the element isolation regions 41, and is a region including one word gate 22, the control gates 24 at both sides, and regions near the gates (source/drain diffusion layers). For example, the memory cell 1 is a region enclosed by a rectangular box shown in FIG. 3. The memory cell 1 shown in FIG. 2 corresponds to a section taken along the line A-A′ in FIG. 3. A contact 52 is connected to a bit line (not shown) with the source/drain diffusion layer 32 of the memory cell 1 arranged as an upper layer.

The lined region 4 has an element isolation region 42 formed on the surface area thereof. A connection layer 25 extends skipping in the Y-direction, while connecting the adjacent control gates 24. The connection layer 25 is connected to a lined wiring (not shown) disposed on the upper layer via a contact 54, as a lined contact structure for the contact gate 24. A lined contact structure for the word gate 22 including the silicide layer (34) and a contact 55 is formed over the word gate 22, and connected to a lined wiring (not shown) disposed on the upper layer.

Next, the operation of the nonvolatile semiconductor memory device according to the first exemplary embodiment will be explained with reference to FIG. 2. First, a writing operation of information into the memory cell 1 will be described. A positive electric potential of about 1 V is applied to the word gate 22. A positive electric potential of about 6 V is also applied to the control gate 24 on the writing side (hereinafter referred to a “selection side”). A positive electric potential of about 3 V is applied to the other control gate 24 opposed to the one control gate 24, and positioned on another side where the writing is not performed (hereinafter referred to as a “non-selection side”). A positive electric potential of about 5 V is applied to the source/drain diffusion layer 32 on the selection side with an electric potential of about 0 V applied to the source/drain diffusion layer 32 on the non-selection side. Thus, hot electrons generated in the channel region are injected into the nitride film of the ONO film 14 on the selection side. This is called CHE (Channel Hot Electron) injection. Thus, data is written.

Next, an erasing operation of the information written in the memory cell 1 will be described below. About 0 V is applied to the word gate 22. A negative electric potential of about −3 V is applied to the control gate 24 on the selection side. A positive electric potential of about 2 V is applied to the control gate 24 on the non-selection side. A positive electric potential of about 5 V is applied to the source/drain diffusion layer 32 on the selection side. Thus, pairs of holes and electrons are generated by interband tunneling, and the holes or holes generated by collision with them are accelerated to become hot holes, which are injected into the nitride film of the ONO film 14 on the selection side. Thus, negative charges stored in the nitride film of the ONO film 14 are cancelled, thereby to erase data.

Now, a reading operation of the information written in the memory cell 1 will be described below. A positive electric potential of about 2 V is applied to the word gate 22. A positive electric potential of about 2 V is applied to the control gate 24 on the selection side. A positive electric potential of about 3 V is applied to the control gate 24 on the non-selection side. A potential of about 0 V is applied to the source/drain diffusion selection 32 on the selection side, and a potential of about 1.5 V is applied to the source/drain diffusion layer 32 on the non-selection side. In this state, a threshold of the memory cell 1 is detected. When the negative charges are stored in the ONO film 14 on the selection side, the threshold is increased as compared to the case where no negative charge is stored. The detection of the threshold can read information written in the ONO film 14 on the selection side. In the memory cell 1 shown in FIG. 2, the information of two bits can be recorded on both sides of the word gate 22, one bit on each side, in the memory cell 1 shown in FIG. 2.

In each operation described above, the application of voltage to the control gates 24, and the following flow of current are provided via the lined contact structure for the control gate shown in FIG. 3. Similarly, the application of voltage to the word gate 22 and the following flow of current are provided via the lined contact structure for the word gate as described above.

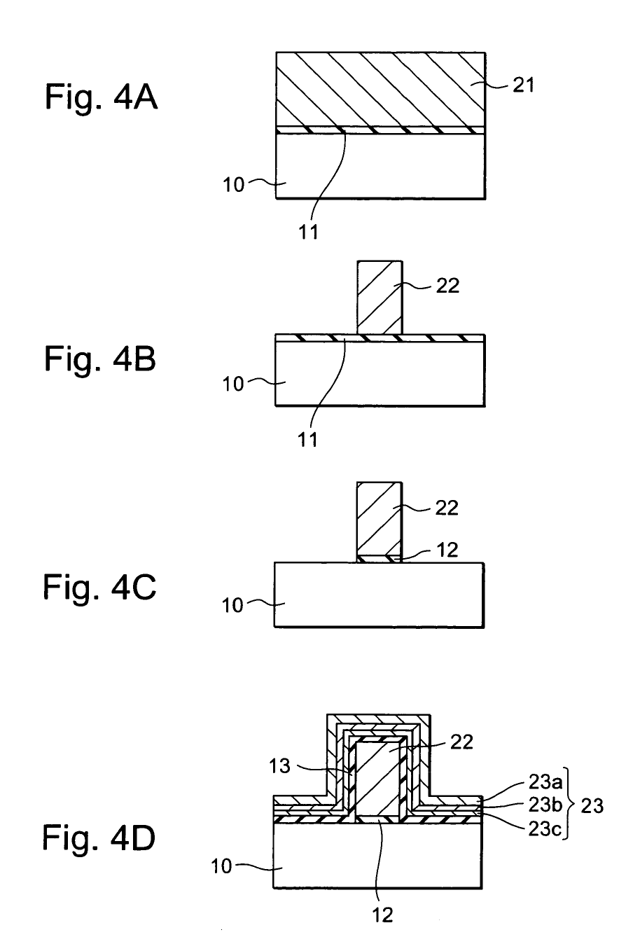

Now, a method for manufacturing the nonvolatile semiconductor memory device according to the first exemplary embodiment of the invention will be described below. FIGS. 4A to 4D, 5A to 5D, 6A to 6D and 7A to 7C are cross-sectional views showing respective steps in the manufacturing method of the nonvolatile semiconductor memory device according to the first exemplary embodiment of the invention. FIGS. 4A to 4D, 5A to 5D, 6A to 6D and 7A to 7C correspond to the section taken along the line A-A′ shown in FIG. 3. The following description will be given with reference to an example where the word gate 22 and the control gate 24 are formed of a polysilicon film, the silicide layer 24a is formed of a nickel silicide film, the silicide reaction inhibition layer 24b is formed of a polysilicon film doped with oxygen, and the polysilicon layer 24c is formed of a polysilicon film.

As shown in FIG. 4A in a first step, the element isolation region 42 (not shown) of the lined region 4 is formed in a predetermined region of the surface of the p-type silicon semiconductor substrate 10, and the element isolation region 41 (not shown) is formed in the memory cell region 3 by a conventional STI (shallow trench isolation) method. A gate insulating film 11 is formed on the surface of the semiconductor substrate 10 by a thermal oxidation process. The gate insulating film 11 has a thickness of, for example, 5 nm. Then, a polysilicon film 21 is formed by a CVD (Chemical Vapor Deposition) method so as to cover the gate insulating film 11. The polysilicon film 21 becomes the word gate 22 of the memory cell 1. The polysilicon film 21 has a thickness (in the z-direction) of, for example, 60 nm to 250 nm.

Then, in a second step as shown in FIG. 4B, the polysilicon film 21 is etched by photolithography and dry etching to form the word gate 22. The gate length (width in the y-direction) of the word gate 22 is, for example, 60 nm to 90 nm. The surface of the gate insulating film 11 is exposed at parts without the word gate 22 thereon.

Then, in a third step as shown in FIG. 4C, the gate insulating film 11 is formed into the word gate insulating film 12 by etching by use of the word gate 22 as a mask. Thus, the word gate insulating film 12 is formed directly under the word gate 22. The surface of the semiconductor substrate 10 is exposed at parts without the word gate 22 thereon.

When material containing at least one of polysilicon and poly-germanium is used as the material for the word gate 22, gas mixed with germanium-containing gas, for example, germane gas (GeH₄ gas), can be used as a film forming gas according to a mixing degree of the germanium in the film.

Subsequently, in a fourth step as shown in FIG. 4D, a silicon oxide film, a silicon nitride film, and a silicon oxide film are laminated in that order so as to cover the surfaces of the semiconductor substrate 10 and of the word gate 22. The first silicon oxide film is formed, for example, in a thickness of 3 nm to 5 nm using a wet oxidation method or a radical oxidation method. The silicon nitride film is formed, for example, in a thickness of 6 nm to 10 nm using the CVD method. The last silicon oxide film is formed, for example, in a thickness of 3 nm to 10 nm by radical oxidation, wet oxidation, or HTO (high temperature) oxidation. Thus, an ONO film 13 serving as a charge storage layer is formed. Then, a polysilicon film 23 is formed by the CVD method so as to cover the ONO film 13.

At this time, a polysilicon film 23c is first formed using film forming gas (for example, silane gas (SiH₄ gas)+hydrogen gas) for forming a polysilicon film. The polysilicon film 23c becomes a polysilicon layer 24c. Then, a polysilicon film 23b containing oxygen atoms is formed using a mixed gas provided by adding a gas containing a small amount of oxygen atoms (for example, oxygen gas) added to the film forming gas. The polysilicon film 23b becomes the silicide reaction inhibition layer 24b. Subsequently, another polysilicon film 23a is formed again using the film forming gas. The polysilicon film 23a becomes a silicide layer 24a by a silicide step to be described later. The polysilicon film 23 is formed, for example, in a thickness of 50 nm to 200 nm. Thereafter, the polysilicon film 23 becomes the control gate 24. It is noted that the polysilicon films 23c to 23a may be continuously formed without stopping the film forming processes, or intermittently formed for each polysilicon film.

When material containing at least one of polysilicon and poly-germanium is used as the material for the control gate 24, gas mixed with germanium-containing gas, for example, germane gas (GeH₄ gas) can be used as a film forming gas according to a mixing degree of the germanium in the film.

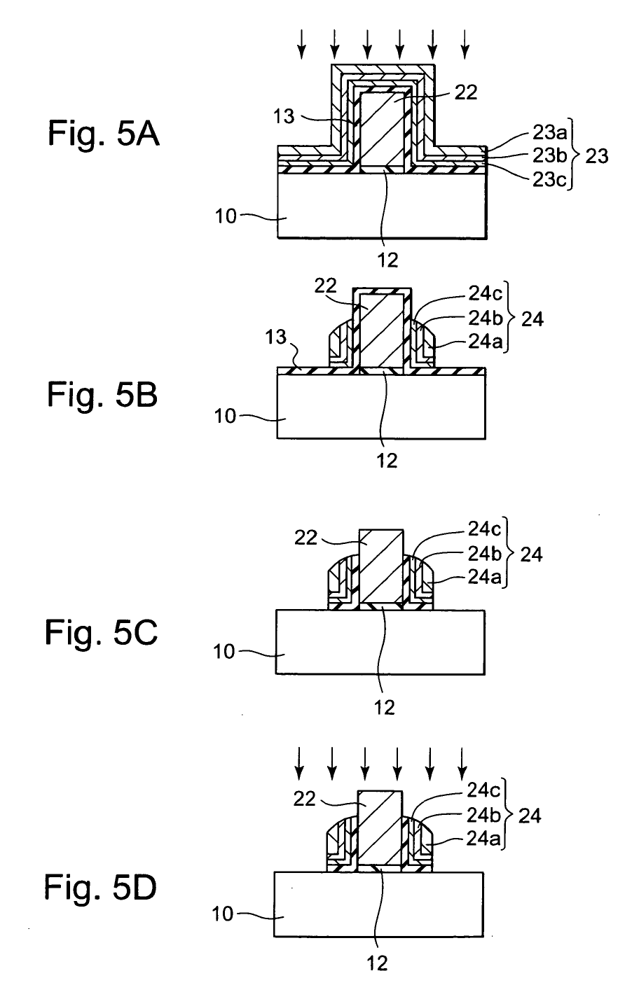

Then, in a fifth step, as shown in FIG. 5A, arsenic (As) ions are implanted into the polysilicon film 23. Preferably, the implantation energy of arsenic (As) is, for example, not less than 1 keV nor more than 30 keV, and the dose amount is not less than 1×10¹⁴/cm² nor more than 5×10¹⁶/cm². After the ion implantation, heat treatment for introducing impurities is performed. The heat treatment conditions are preferably as follows: the temperature is not less than 800° C. nor more than 1100° C., and the time is not less than 10 seconds nor more than 120 seconds. The polysilicon film 23 may be doped with arsenic (As) in the film forming process shown in FIG. 4D. The concentration of arsenic (As) is preferably not less than 1×10¹⁹/cm³ nor more than 5×10²²/cm³.

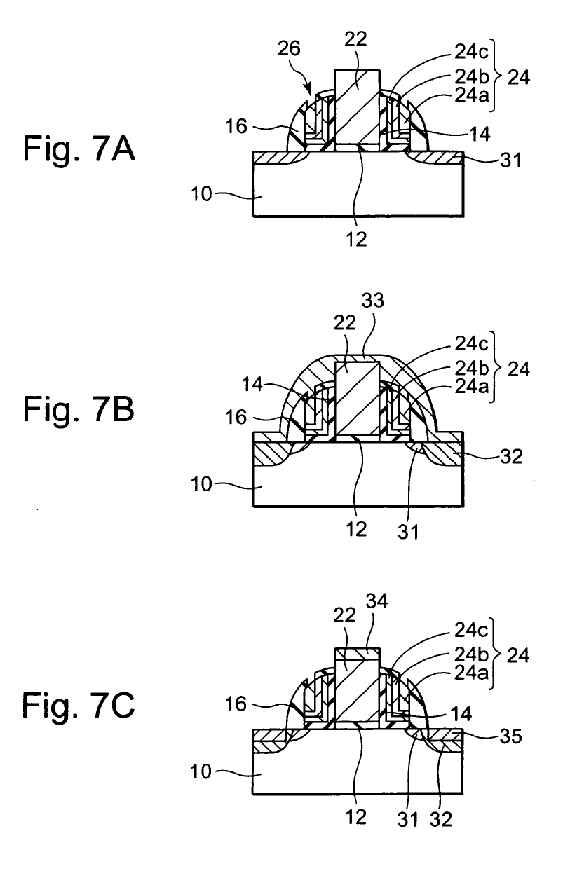

Subsequently, in a sixth step as shown in FIG. 5B, the polysilicon film 23 is etched back to remove parts of the polysilicon film 23 other than those near the sides of the word gate 22. Thus, the control gates 24 are formed at the sides of the word gate 22 via the ONO film 13. At this time, in the control gate 24, the polysilicon layer 24c, the silicide reaction inhibition layer 24b, and the silicide layer 24a are formed in that order from the side in contact with the ONO film 13. It is noted that the silicide layer 24c will be silicided in the following steps (see FIGS. 7B and 7C). At this stage, the silicide layer is still a polysilicon film.

Thereafter, in a seventh step as shown in FIG. 5C, the ONO film 13 is etched back to remove the exposed part of the ONO film 13. Thus, the surface of an upper part of the word gate 22 and the surface of a part of the semiconductor substrate 10 outside the control gate 24 are exposed. Accordingly, the ONO film 14 is formed between the word gate 22 and the control gate 24, and between the semiconductor substrate 10 and the control gate 24.

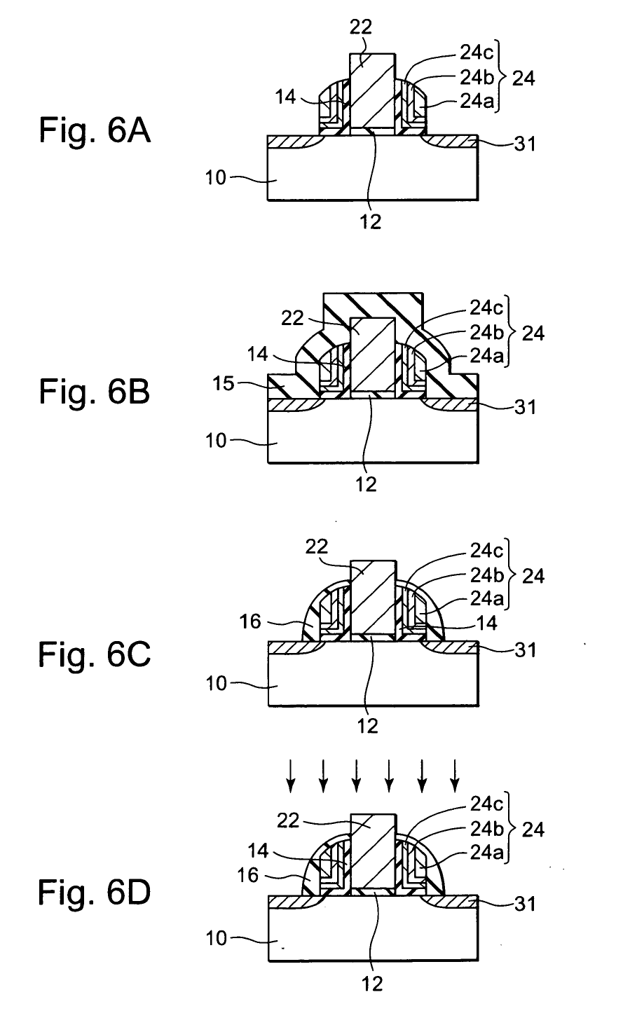

Then, in an eighth step as shown in FIG. 5D, arsenic (As) or phosphorus (P) ions for a lightly doped drain (LDD) are implanted into the surface of the exposed part of the semiconductor substrate 10 using the word gate 22, the ONO film 14, and the control gate 24 as a mask. The implantation energy of the arsenic (As) or phosphorus (P) is not less than 2 keV nor more than 30 keV, and the dose amount is not less than 1×10¹³/cm² nor more than 1×10¹⁵/cm². Thus, an LDD diffusion layer 31 is formed in a self-aligned manner (see ninth step in FIG. 6A).

Subsequently, in a tenth step as shown in FIG. 6B, a sidewall insulating film 15 is formed by the CVD method so as to cover the part of the surface of the semiconductor substrate 10, the word gate 22, the ONO film 14, and the control gate 24. The sidewall insulating film 15 has, for example, a three-layered structure of a silicon oxide film, a silicon nitride film, and a silicon oxide film, or a single layer of silicon oxide. The sidewall insulating film 15 is formed, for example, in a thickness of 20 nm to 150 nm.

Thereafter, in an eleventh step as shown in FIG. 6C, the sidewall insulating film 15 is etched back to form the sidewall insulating film 16 at the side of the word gate 22. At this time, the upper part of the word gate 22 and the part of the surface of the semiconductor substrate 10 are exposed. It is noted that the side and upper part of the control gate 24 are covered with the sidewall insulating film 16.

Then, in a twelfth step as shown in FIG. 6D, arsenic (As) or phosphorus (P) ions for the source/drain diffusion layer are implanted into the exposed part of the surface of the semiconductor substrate 10 respectively using the word gate 22 and the sidewall insulating film 16 as a mask in the memory cell region 3. Preferably, the implantation energy of arsenic (As) or phosphorus (P) is not less than 5 keV nor more than 50 keV, and the dose amount is not less than 1×10¹⁴/cm² nor more than 1×10¹⁶/cm². Thereafter, a lamp annealing process (heat treatment) is performed at a temperature of not less than 950° C. nor more than 1100° C. for a time of more than 0 and not more than 120 seconds so as to activate the part ion-implanted. Thus, the source/drain diffusion layer 32 is formed in a self-aligned manner.

Then, in a thirteenth step as shown in FIG. 7A, a part of the side wall insulating film 16 for covering the upper part of the silicide layer 24a of the control gate 24 is removed by photolithography and dry etching to form an opening 26. An upper part of the silicide layer 24a is exposed via the opening 26.

Subsequently, in a fourteenth step as shown in FIG. 7B, a nickel film 33 is formed by sputtering so as to cover the entire upper surface of the semiconductor substrate 10, and then heat treatment is performed. In the heat treatment, an upper part of the word gate 22, the surface of the source/drain diffusion layer 32, and the entire silicide layer 24a are respectively silicided to become the silicide layers 34 and 35, and the silicide layer 24a, respectively.

At this time, the silicide reaction inhibition layer 24b in the control gate 24 is formed of silicon containing at least one of oxygen and carbon, which hardly permits diffusion of nickel components for the silicide process. Thus, the silicide reaction inhibition layer 24b is not silicided. Since the silicide reaction inhibition layer 24b inhibits the diffusion of nickel for the silicide process, and the sidewall insulating film 16 protects the upper part of the polysilicon layer 24c, the polysilicon layer 24c is not silicided. Further, the sidewall insulating film 16 protects the upper part of the ONO film 14, whereby the ONO film 14 is not silicided.

Even when the silicide reaction inhibition layer 24b is exposed due to the slight misalignment of the opening 26, the silicide reaction inhibition layer 24b is a layer which is substantially less prone to be silicided, and thus is actually not silicided. Therefore, the opening 26 is allowed to be displaced by a thickness of the silicide reaction inhibition layer 24b.

Then, in a fifteenth step as shown in FIG. 7C, the nickel film 33 remaining over the entire upper surface of the semiconductor substrate 10 is removed. This state is illustrated in FIG. 2. After the above manufacturing steps, an interlayer insulating layer and a contact are formed thereby to manufacture the nonvolatile semiconductor memory device.

In the step of forming the polysilicon film 23 among the above manufacturing steps, the polysilicon films 23a, 23b, and 23c are formed, while temporarily mixing an additive gas containing at least one of oxygen and carbon (for example, oxygen) into a film forming gas during forming the film. Thus, the control gate 24 has a three-layered structure of the polysilicon film 23c obtained before mixing of the additive gas, the polysilicon film 23b obtained during mixing of the additive gas, and the polysilicon film 23a obtained after mixing of the additive gas. Mixing of the additive gas during the film forming can easily manufacture the polysilicon film 23 having the above-mentioned three-layered structure. Among them, the polysilicon film 23a is silicided in the silicide step to become the silicide layer 24a. In the polysilicon film 23b, the diffusion of metal for silicide (for example, nickel) is inhibited by the effectiveness of oxygen or carbon in the additive gas. The polysilicon film 23b becomes the silicide reaction inhibition layer 24b in which the silicide reaction is inhibited. The polysilicon film 23c becomes the polysilicon layer 24c which is not silicided because the diffusion of nickel is inhibited by the silicide reaction inhibition layer 24b. In this way, the manufacturing method of the invention can easily manufacture the control gate 24 having the three-layered structure. A nonvolatile semiconductor memory device including the control gate 24 manufactured in such steps has the same operation and effect as those of the above-mentioned nonvolatile semiconductor memory device.

In the nonvolatile semiconductor memory device of the invention, the control gate 24 includes the three-layered structure of the silicide layer 24a, the silicide reaction inhibition layer 24b, and the polysilicon layer 24c. The silicide layer 24a is provided by silicide containing nickel. Therefore, even when the control gate 24 is thinned, the entire silicide layer 24a can be easily silicided fully. Thus, the resistance of the memory device can be made lower.

The silicide layer 24a and the silicide reaction inhibition layer 24b are provided between the silicide layer 24a and the ONO film 14, that is, between the silicide layer 24a and the word gate 22. Therefore, a distance between the silicide layer 24a and the word gate 22 is widened by the thicknesses of the silicide layer 24a and the silicide reaction inhibition layer 24b, thus being separated from each other. Thus, even when the nitride film exposed to the section of the ONO film 14 is partly silicided, the silicide layer 24a and the word gate 22 are largely separated from each other, which can prevent the occurrence of short-circuiting.

The presence of the silicide layer 24a and the silicide reaction inhibition layer 24b does not bring the silicide layer 24a with a low resistance into direct contact with the ONO film 14. Therefore, the influences of the electric state of the silicide layer 24a (for example, variations in voltage) and of the state of the oxide film on the silicide layer 24a side of the ONO film 14 (for example, nonuniformity in film thickness) can be reduced to a much smaller level. The nickel components in the silicide layer 24a can be prevented from being diffused into the ONO film 14, and the charges stored in the nitride film can be prevented from being pulled into the nickel components. Thus, the state of charges stored in the nitride film can be made more stable, and the distribution of charges can be made more uniform, which can prevent the degradation of quality of the ONO film. As a result, the reliability and stability of the nonvolatile semiconductor memory device can be enhanced.

The above-mentioned control gate structure can be applied to a memory cell having a planar type MONOS structure (for example, a split-gate type MONOS structure, a F-MONOS structure) in the same way.

Although the invention has been described above in connection with the exemplary embodiment thereof, it will be appreciated by those skilled in the art that that exemplary embodiment is provided solely for illustrating the invention, and should not be relied upon to construe the appended claims in a limiting sense.

Further, it is noted that, notwithstanding any claim amendments made hereafter, applicant's intent is to encompass equivalents all claim elements, even if amended later during prosecution.

What is claimed is:

1. A nonvolatile semiconductor memory device, comprising:
a word gate provided above a channel region of a semiconductor substrate via an insulating layer;
a control gate provided at a side of the word gate; and
a charge storage layer provided by an ONO film between the channel region and the control gate, and between the word gate and the control gate,
wherein the control gate includes:
a silicide layer including silicide containing nickel; and
a non-silicide layer provided between the silicide layer and the charge storage layer.

2. The nonvolatile semiconductor memory device according to claim 1,
wherein the non-silicide layer includes:
a silicide reaction inhibition layer provided between the silicide layer and the charge storage layer; and
a polysilicon layer provided between the silicide reaction inhibition layer and the charge storage layer.

3. The nonvolatile semiconductor memory device according to claim 2,
wherein the silicide reaction inhibition layer is provided by at least one of silicon and germanium containing at least one of oxygen and carbon.

4. The nonvolatile semiconductor memory device according to claim 1,
wherein the word gate includes a silicide layer including nickel at an upper part thereof.

5. The nonvolatile semiconductor memory device according to claim 1,
wherein a height of the control gate is larger than a width of the control gate.

6. The nonvolatile semiconductor memory device according to claim 5,
wherein the width of the control gate is equal to or less than 60 nm.

7. The nonvolatile semiconductor memory device according to claim 1,
wherein the ONO film includes a laminated film of a silicon oxide film, a silicon nitride film, and a silicon oxide film.

8. A method of manufacturing a nonvolatile semiconductor memory device, comprising:
forming an ONO film so as to cover a word gate formed above a semiconductor substrate via an insulating layer;
forming a polysilicon film so as to cover the ONO film;
forming a control gate at a side of the word gate via the ONO film by etching the polysilicon film;
etching the ONO film over the word gate and outside the control gate;
siliciding an upper part of the word gate, a part of the control gate, and a part outside the control gate by forming a metal film including nickel over an entire surface and applying heat treatment thereto; and
removing the metal film,
wherein the forming of the polysilicon film includes:
forming the polysilicon film while temporarily mixing an additive gas including at least one of oxygen and carbon into a film-forming gas during forming the polysilicon film.

9. The method of manufacturing a nonvolatile semiconductor memory device according to claim 8,
wherein the etching of the ONO film includes:
covering a section of the ONO film exposed by the etching with a second insulating layer.
